(19) United States
(12) Patent Application Publication
(10) Pub. No.: US 2017/0234744 A1
(43) Pub. Date: Aug. 17, 2017

(54) MEMS FORCE SENSOR AND FORCE SENSING APPARATUS

(71) Applicant: GlobalMEMS Co., Ltd., Grand Cayman (KY)

(72) Inventors: Hsi-Wen Tung, Taipei City (TW); Ming-Ching Wu, Taoyuan City (TW)

(21) Appl. No.: 15/134,395

(22) Filed: Apr. 21, 2016

(30) Foreign Application Priority Data
Feb. 16, 2016 (TW) 105104409

(51) Int. Cl. G01L 1/18; G06F 3/041; B81B 7/00

(52) U.S. Cl. CPC G01L 1/18; B81B 7/0016; G06F 3/0414; B81B 2201/0264

(57) ABSTRACT

A MEMS force sensor including a first substrate, a second substrate and a plurality of conductive terminals is provided. The second substrate is disposed opposite to the first substrate and includes a deformable portion and a force receiving portion. The deformable portion has a plurality of sensing elements. The force receiving portion protrudes from a surface of the deformable portion which is back facing to the first substrate, such that a cavity is formed above the deformable portion. The conductive terminals are electrically connected to the sensing elements, and the conductive terminals are centrally disposed under the cavity. The second substrate is fixed with the first substrate through the conductive terminals. A force sensing apparatus is also provided.

### CROSS-REFERENCE TO RELATED APPLICATION

This application claims the priority benefit of Taiwan application serial no. 105104409, filed on Feb. 16, 2016. The entirety of the above-mentioned patent application is hereby incorporated by reference herein and made a part of this specification.

### BACKGROUND

Field of the Invention

The invention relates to a micro-electro-mechanical system (MEMS) sensor and a sensing apparatus and more particularly to an MEMS force sensor and a force sensing apparatus.

Description of Related Art

A micro-electro-mechanical system (MEMS) technique refers to a design based on a miniaturized electro-mechanical integrated structure. At present, the common MEMS techniques are mainly applied in three major fields, i.e., micro sensor, micro actuator and micro structure elements. Among them, the micro sensor can be used to convert an external environmental changes (e.g., forces, pressures, sounds, speeds, etc.) into electrical signals (e.g., voltages or currents), thereby achieving environmental sensing functions, such as force sensing, pressure sensing, sound sensing, acceleration sensing and so on. The micro sensor may be fabricated by using a semiconductor fabrication process and integrated with an integrated circuit, thus has preferable competitiveness. Accordingly, an MEMS sensor and a sensing apparatus applying the MEMS sensor in fact become the development trend of MEMS systems.

### SUMMARY

The invention provides a micro-electro-mechanical system (MEMS) force sensor capable of sensing a change of a force applied to the MEMS force sensor.

The invention provides a force sensing apparatus capable of sensing a change of a force applied to the force sensing apparatus.

According to an embodiment of the invention, an MEMS force sensor including a first substrate, a second substrate and a plurality of conductive terminals is provided. The second substrate is disposed opposite to the first substrate and includes a deformable portion and a force receiving portion. The deformable portion has a plurality of sensing elements. The force receiving portion protrudes from a surface of the deformable portion which is back facing to the first substrate, such that a cavity is formed above the deformable portion. The conductive terminals are electrically connected to the sensing elements, and the conductive terminals are centrally disposed under the cavity. The second substrate is fixed with the first substrate through the conductive terminals.

In an embodiment of the invention, the first substrate is a printed circuit board (PCB) or a display panel.

In an embodiment of the invention, the sensing elements include a plurality of connection portions and a plurality of piezoresistive sensing elements. Each of the piezoresistive sensing elements is connected with two adjacent connection portions. Each of four sides of the deformable portion has a sensing unit. The sensing unit is composed of at least one of the piezoresistive sensing elements and multiple of the connection portions.

In an embodiment of the invention, orthographic projections of the piezoresistive sensing elements on the surface of the deformable portion which is back facing to the first substrate fall within a range covered by the cavity.

In an embodiment of the invention, the sensing elements are disposed near a central region of the deformable portion, and orthographic projections of the sensing elements and the piezoresistive sensing elements on the surface of the deformable portion which is back facing to the first substrate fall within the range covered by the cavity.

In an embodiment of the invention, the second substrate further includes a circuit structure. The circuit structure is disposed on a surface of the deformable portion facing the first substrate, and the sensing elements are electrically connected to the conductive terminals through the circuit structure. Therein, two adjacent sensing units share one of the conductive terminals through the circuit structure and form a Wheatstone bridge.

In an embodiment of the invention, the MEMS force sensor further includes an overload protection layer. The overload protection layer is filled in the cavity, and a top surface of the overload protection layer is higher than a top surface of the force receiving portion.

In an embodiment of the invention, a rigidity of the overload protection layer is less than a rigidity of the second substrate.

In an embodiment of the invention, the MEMS force sensor further includes an overload protection layer. The overload protection layer is disposed on a surface of the deformable portion facing the first substrate and exposes the conductive terminals. A gap is kept between the overload protection layer and the first substrate.

According to an embodiment of the invention, a force sensing apparatus including an MEMS force sensor and a third substrate is provided. The MEMS force sensor includes a first substrate, a second substrate and a plurality of conductive terminals. The second substrate is disposed opposite to the first substrate and includes a deformable portion and a force receiving portion. The deformable portion has a plurality of sensing elements. The force receiving portion protrudes from a surface of the deformable portion which is back facing to the first substrate, such that a cavity is formed above the deformable portion. The conductive terminals are electrically connected to the sensing elements, and the conductive terminals are centrally disposed under the cavity. The second substrate is fixed with the first substrate through the conductive terminals. The third substrate has a protruding portion, a width of the protruding portion is less than a width of the cavity, and a thickness of the protruding portion is less than a depth of the cavity. The third substrate is assembled onto the second substrate, and the protruding portion is embedded in the cavity.

In an embodiment of the invention, the third substrate is a substrate of a touch panel or a substrate of a display panel.

To sum up, in the embodiments of the invention, the deformable portion has a plurality of sensing elements, and the force receiving portion protrudes from the surface of the deformable portion which is back facing to the first substrate. When an external force is applied to the force receiving portion, the deformable portion receives a pressing-down force and is deformed, and the sensing elements in the deformable portion correspondingly generate a physical quantity change, such that the MEMS force sensor and the force sensing apparatus having the MEMS force sensor can determine the change of the force applied to the MEMS force sensor or the force sensing apparatus according to the physical quantity change.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1 is a schematic cross-sectional view of a micro-electro-mechanical system (MEMS) force sensor according to an embodiment of the invention.

FIG. 2 is a schematic bottom view of a first implementation form of the MEMS force sensor depicted in FIG. 1.

FIGS. 3A to 3J are schematic cross-sectional views of a fabrication process of the MEMS force sensor depicted in FIG. 2.

FIG. 4 is a schematic bottom view of a second implementation form of the MEMS force sensor depicted in FIG. 1.

FIG. 5 is a schematic bottom view of a third implementation form of the MEMS force sensor depicted in FIG. 1.

FIGS. 6A and 6B are respectively a schematic cross-sectional view and a schematic bottom view of a fourth implementation form of the MEMS force sensor depicted in FIG. 1.

FIG. 7 is a schematic cross-sectional view of a force sensing apparatus according to an embodiment of the invention.

### DESCRIPTION OF EMBODIMENTS

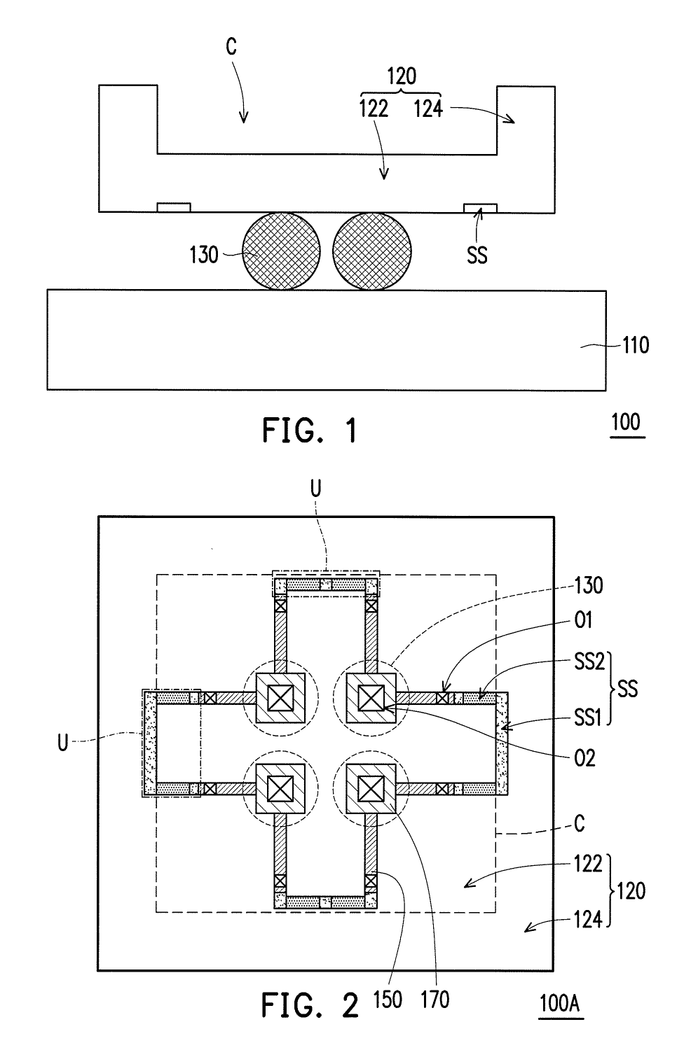

FIG. 1 is a schematic cross-sectional view of a micro-electro-mechanical system (MEMS) force sensor according to an embodiment of the invention. With reference to FIG. 1, an MEMS force sensor 100 includes a first substrate 110, a second substrate 120 and a plurality of conductive terminals 130. The second substrate 120 is disposed opposite to the first substrate 110 and includes a deformable portion 122 and a force receiving portion 124. The deformable portion 122 has a plurality of sensing elements SS. The force receiving portion 124 protrudes from a surface of the deformable portion 122 which is back facing to the first substrate 110, such that a cavity C is formed above the deformable portion 122. The conductive terminals 130 are electrically connected to the sensing elements SS, and the conductive terminals 130 are centrally disposed under the cavity C. The second substrate 120 is fixed with the first substrate 110 through the conductive terminals 130.

The first substrate 110 may be a printed circuit board (PCB), a display panel or any other suitable substrate, and the first substrate 110 has a circuit suitable for exporting electrical signals to a processor. The second substrate 120 may be a semiconductor substrate, and the deformable portion 122 and the force receiving portion 124 may be formed through a patterning process. The force receiving portion 124 is disposed around the edge of the deformable portion 122, such that the cavity C is located in the center of the second substrate 120. The aforementioned semiconductor substrate is, for example, a silicon-on-insulator (SOI) substrate, but the invention is not limited thereto. The conductive terminals 130 are located between the first substrate 110 and the second substrate 120, and the conductive terminals 130 may export the electrical signals and serve as mechanical fixing terminals. In the present embodiment, the conductive terminals 130 are solder balls having advantages, such as good conductivity, no need to package and small volume.

The sensing elements SS are disposed near a surface of the deformable portion 122 facing the first substrate 110 and are disposed near the edge of the deformable portion 122, which is not limited in the invention. In another embodiment, the sensing elements SS may also be disposed near a central region of the deformable portion 122. The second substrate 120 may further include a circuit structure (not shown) for electrically connecting the sensing elements SS with the conductive terminals 130. In this way, when an external force is applied to the force receiving portion 124, the deformable portion 122 is deformed by a pressing-down force received by the force receiving portion 124, such that the sensing elements SS in the deformable portion 122 correspondingly generate a physical quantity change. The aforementioned physical quantity change correspondingly causes a change in an electrical signal, and the change in the electrical signal may be output through the circuit structure and the conductive terminals 130 in sequence to an external circuit (e.g., the processor) for subsequent signal processing and analysis. In this way, the MEMS force sensor 100 may determine the change of the force applied thereto.

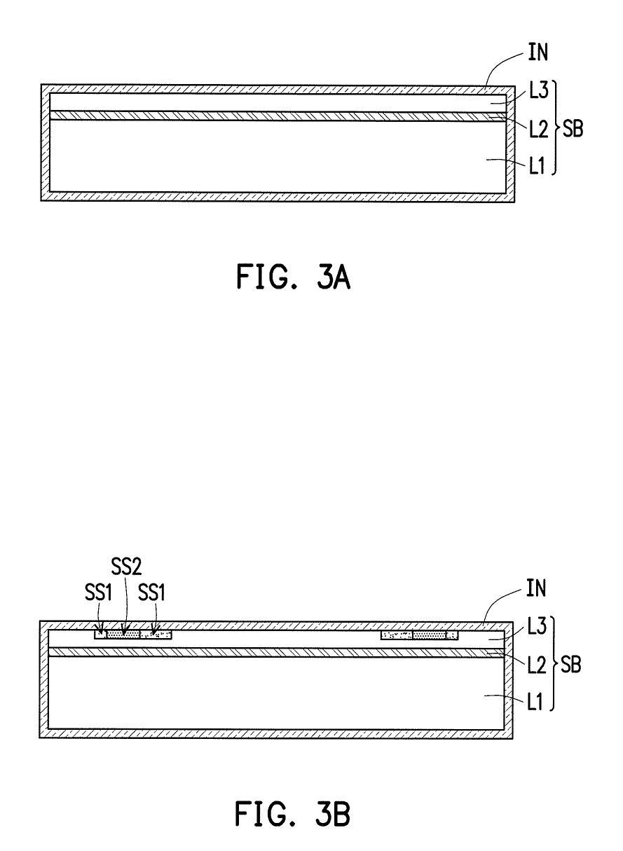

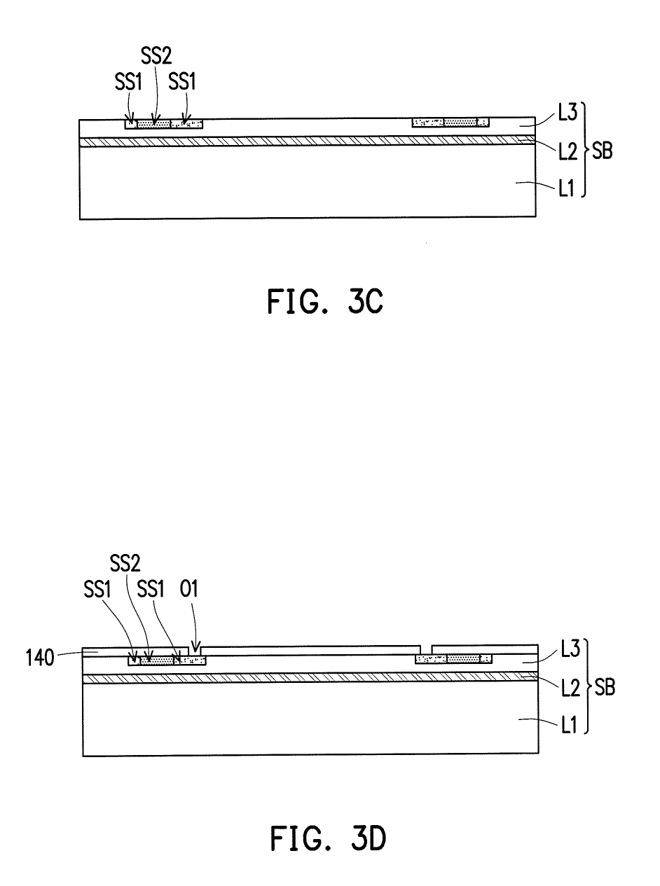

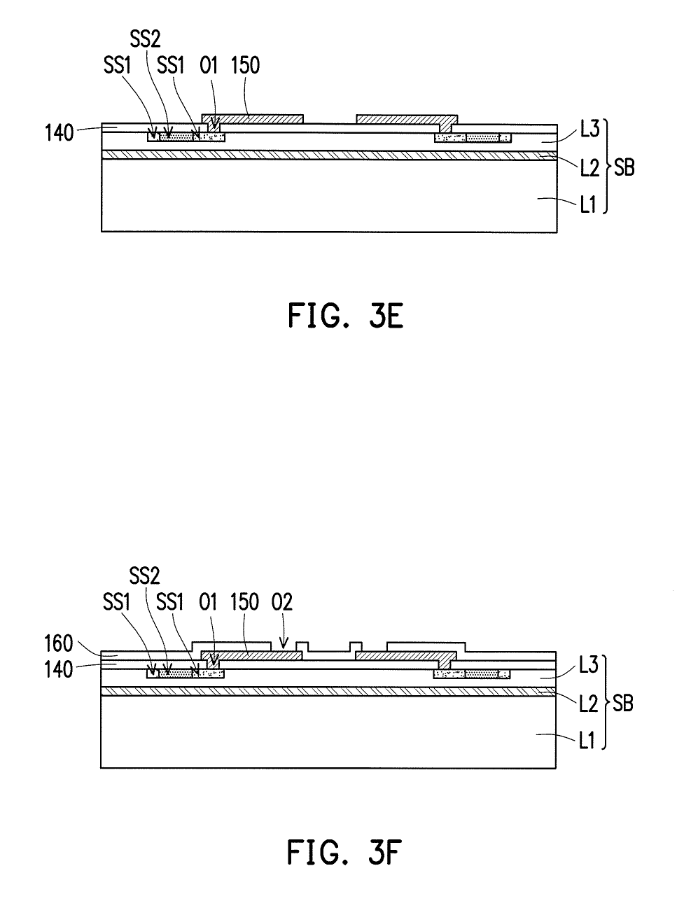

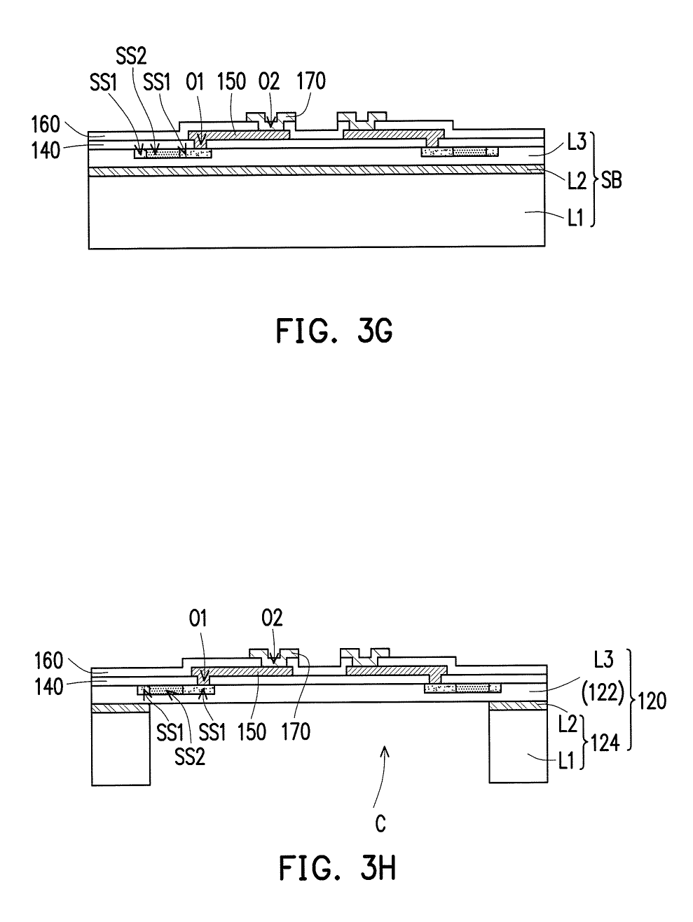

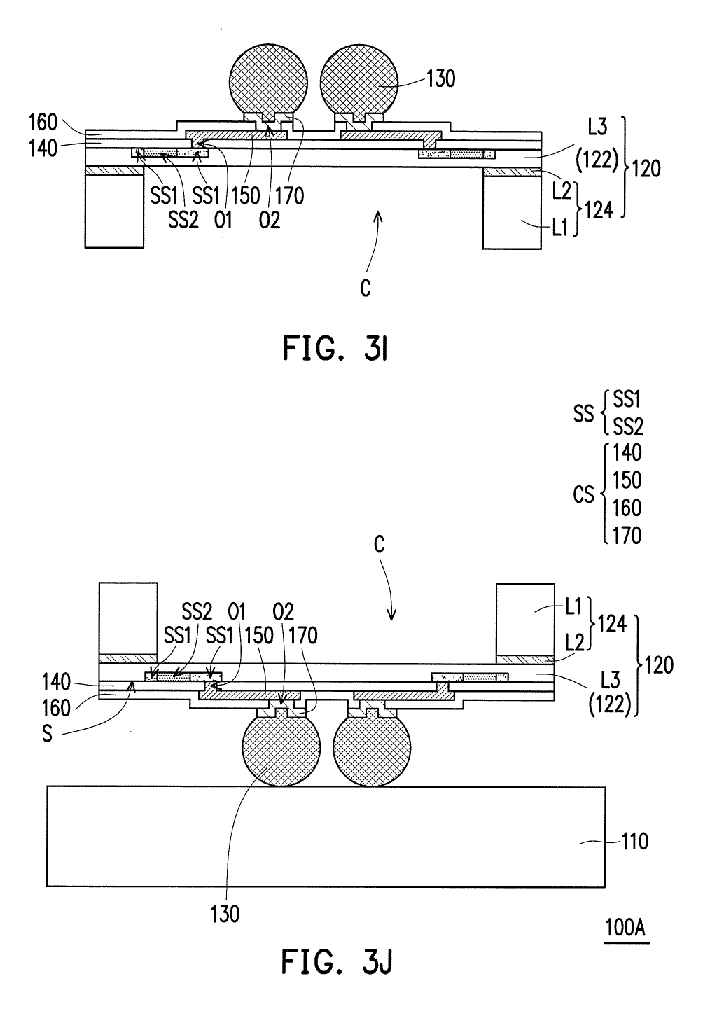

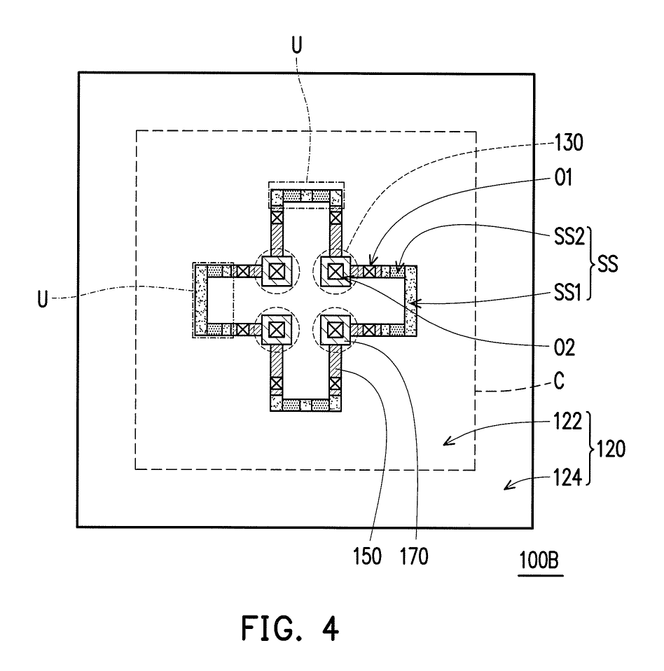

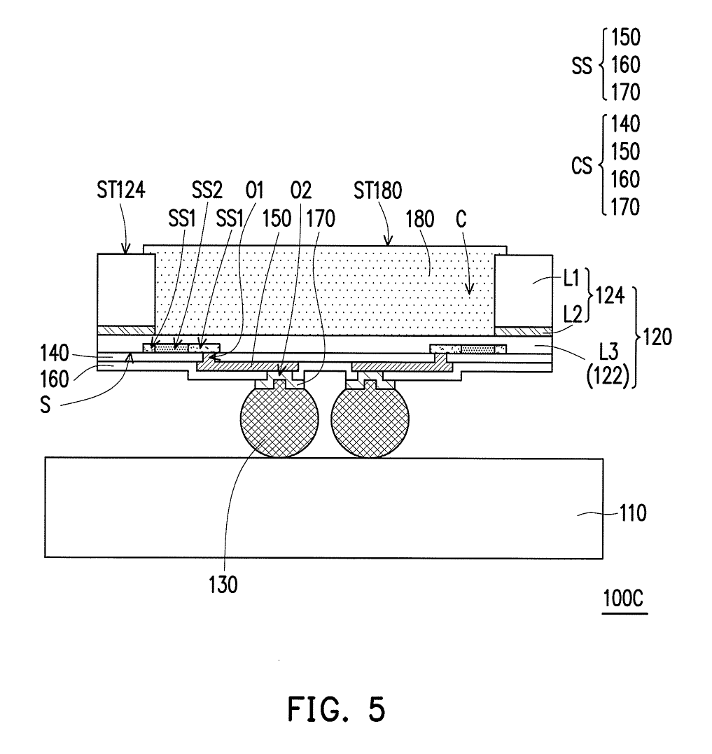

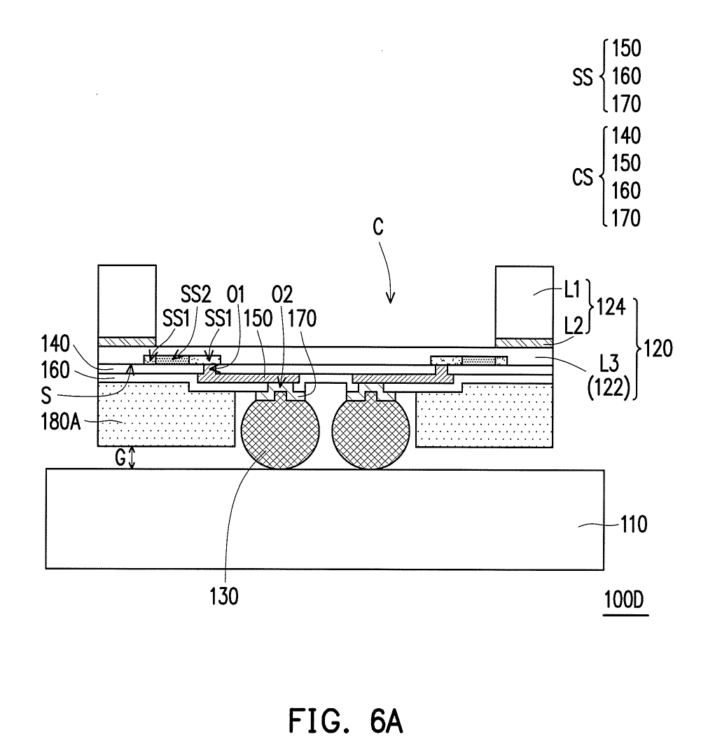

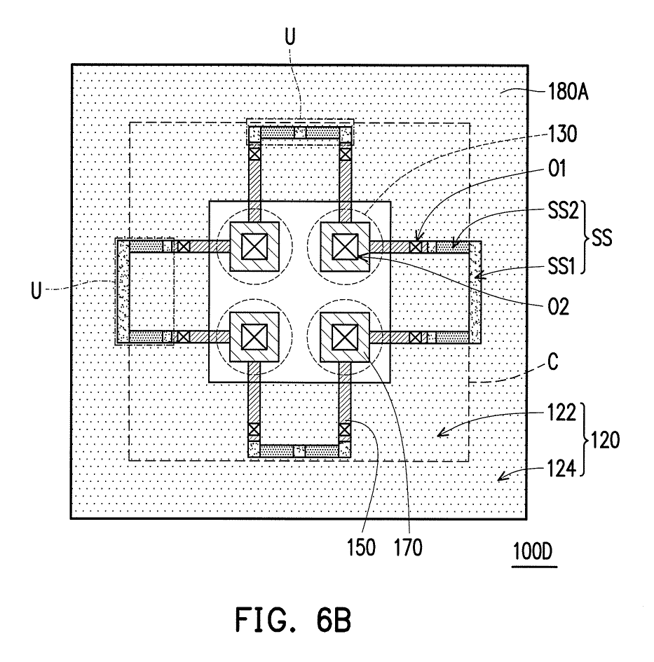

Several specific implementation forms of the MEMS force sensor 100 will be described with reference to FIGS. 2 to 6B. Therein, the same or like elements are labeled by the same or like reference numbers and will not be repeatedly described. FIG. 2 is a schematic bottom view of a first implementation form of the MEMS force sensor depicted in FIG. 1. FIGS. 3A to 3J are schematic cross-sectional views of a fabrication process of the MEMS force sensor depicted in FIG. 2. FIG. 4 is a schematic bottom view of a second implementation form of the MEMS force sensor depicted in FIG. 1. FIG. 5 is a schematic bottom view of a third implementation form of the MEMS force sensor depicted in FIG. 1. FIGS. 6A and 6B are respectively a schematic cross-sectional view and a schematic bottom view of a fourth implementation form of the MEMS force sensor depicted in FIG. 1. In order to illustrate the sensing elements and the circuit structure more clearly, the first substrate 110 is omitted in FIGS. 2, 4 and 6B, and the conductive terminals 130 are presented in dotted lines.

Referring to FIGS. 6A and 3J first, in an MEMS force sensor 100A, the sensing elements SS may include a plurality of connection portions SS1 and a plurality of piezoresistive sensing elements SS2. Each of the piezoresistive sensing elements SS2 is connected with two adjacent connection portions SS1, and orthographic projections of the piezoresistive sensing elements SS2 on the surface of the deformable portion 122 which is back facing to the first substrate 110 fall within a range covered by the cavity C. Namely, edges of the piezoresistive sensing elements SS2 do not exceed the range covered by the cavity C (the range covered by the cavity C is presented in dashed lines in FIG. 2).

Each of four sides of the deformable portion 122 has a sensing unit U. Each sensing unit U is composed of at least one of the piezoresistive sensing elements SS2 and multiple of the connection portions SS1. For example, each sensing unit U is composed of two piezoresistive sensing elements SS2 and three connection portions SS1, but the invention is not limited thereto.

Referring to FIG. 3J, the second substrate 120 further includes a circuit structure CS. The circuit structure CS is disposed on a surface S of the deformable portion 122 facing the first substrate 110, and the sensing elements SS are electrically connected to the conductive terminals 130 through the circuit structure CS. Therein, two adjacent sensing units U share one of the conductive terminals 130 through the circuit structure CS and form a Wheatstone bridge.

In the present embodiment, the circuit structure CS includes a first inter-layer dielectric layer 140, a plurality of conductive wires 150, a second inter-layer dielectric layer 160 and a plurality of pads 170. The first inter-layer dielectric layer 140 is disposed on the surface S of the deformable portion 122 facing the first substrate 110. The first inter-layer dielectric layer 140 has a plurality of first openings O1. Each of the first openings O1 exposes a portion of one of the connection portions SS1. The conductive wires 150 are disposed on the first inter-layer dielectric layer 140. The portion of each of the connection portions SS1 is connected with one of the conductive wires 150. The second inter-layer dielectric layer 160 is disposed on the first inter-layer dielectric layer 140 and the conductive wires 150, and the second inter-layer dielectric layer 160 has a plurality of second openings O2. Each of the second openings O2 exposes a portion of one of the conductive wires 150. The pads 170 are disposed on the second inter-layer dielectric layer 160. Each of the pads 170 is connected with the portion of a corresponding conductive wire 150 through one of the second openings O2. Each of the conductive terminals 130 is connected to one of the pads 170 to export an electrical signal from the second substrate 120.

A fabrication process of the MEMS force sensor 100A will be described as follow. Referring to FIG. 3A, a substrate SB is provided. The substrate SB is, for example, an SOI substrate. For example, the substrate SB may be formed by stacking a first layer L1, a second layer L2 and a third layer L3. The first layer L1 and the third layer L3 may be silicon substrates, while the second layer L2 may be an insulating layer, e.g., a silicon oxide layer, but the invention is not limited thereto.

Then, an insulating layer IN is formed on the substrate SB. The insulating layer IN, for example, covers all surfaces of the substrate SB, but the invention is not limited thereto. The insulating layer IN is, for example, a silicon oxide layer, but the invention is not limited thereto.

Referring to FIG. 3B, the sensing elements SS (including the connection portions SS and the piezoresistive sensing elements SS2) are formed in the third layer L3. A method for forming the connection portions SS1 and the piezoresistive sensing elements SS2 includes, for example, ion doping, and a doping concentration of each piezoresistive sensing element SS2 is less than a doping concentration of each connection portion SS1.

Referring to FIG. 3C, the insulating layer IN is removed. A method for removing the insulating layer IN includes etching. An etchant used for etching includes, for example, buffered oxide etchant (BOE), but the invention is not limited thereto.

Referring to FIG. 3D, the first inter-layer dielectric layer 140 is formed on the third layer L3, wherein the connection portions SS1 and the piezoresistive sensing elements SS2 are located between the first inter-layer dielectric layer 140 and the second layer L2. The first inter-layer dielectric layer 140 has a plurality of first openings O1. Each of the first openings O1 exposes a portion of one of the connection portions SS1. A method for forming the first inter-layer dielectric layer 140 may include forming a first inter-layer dielectric material layer on the third layer L3 by means of plasma enhanced chemical vapor deposition (PECVD) and then forming the first openings O1 by means of wet-etching, but the invention is not limited thereto. A material of the first inter-layer dielectric layer 140 may be silicon oxide or silicon nitride, but the invention is not limited thereto.

Referring to FIG. 3E, a plurality of conductive wires 150 are formed on the first inter-layer dielectric layer 140, wherein the portion of each of the connection portions SS1 is connected with one of the conductive wires 150. A method for forming the conductive wires 150 may include forming a conductive layer by means of sputtering and then patterning the conductive layer by means of dry etching, so as to form the conductive wires 150, but the invention is not limited thereto.

Referring to FIG. 3F, the second inter-layer dielectric layer 160 is formed on the first inter-layer dielectric layer 140 and the conductive wires 150. The second inter-layer dielectric layer 160 has a plurality of second openings O2. Each of the second openings O2 exposes a portion of one of the conductive wires 150. A method for forming the second inter-layer dielectric layer 160 includes forming a second inter-layer dielectric material layer by means of PECVD, and then forming the second openings O2 by means of dry etching, but the invention is not limited thereto. A material of the second inter-layer dielectric layer 160 may be silicon nitride, but the invention is not limited thereto.

Referring to FIG. 3G, a plurality of pads 170 are formed on the second inter-layer dielectric layer 160. Each of the pads 170 is connected with the portion of a corresponding conductive wire 150 through one of the second openings O2. A method for forming the pads 170 may include forming a conductive layer by means of sputtering and then patterning the conductive layer by means of dry etching, so as to form the pads 170, but the invention is not limited thereto.

Referring to FIG. 3H, a portion of the first layer L1 and a portion of the second layer L2 are removed to form the second substrate 120. The second substrate 120 includes the deformable portion 122 and the force receiving portion 124, wherein the deformable portion 122 is composed of, for example, the third layer L3, and the force receiving portion 124 is composed of, for example, the patterned second layer L2 and the patterned first layer L1. The force receiving portion 124 protrudes from the surface of the deformable portion 122, such that a cavity C is formed above the deformable portion 122.

Referring to FIG. 3I, conductive terminals 130 are formed on the pads 170. A method of forming the conductive terminals 130 may include printing, but the invention is not limited thereto.

Referring to FIG. 3J, the first substrate 110 is bonded with the second substrate 120 through the conductive terminals 130.

Based on different demands, a person ordinarily skilled in the art may change the sequence of the fabrication process or additionally dispose other elements or layers, or change shapes of the elements or relative disposition relations, without departing the spirit or scope of the invention. For example, referring to FIG. 4, in an MEMS force sensor 100B, the sensing elements SS may be disposed near a central region of the deformable portion 122. In this architecture, orthographic projections of the connection portions SS1 and the piezoresistive sensing elements SS2 on a surface of the deformable portion 122 which is back facing to the first substrate 110 fall, for example, within a range covered by the cavity C (a range covered by the cavity C is presented in dashed lines in FIG. 4).

Besides, referring to FIG. 5, an MEMS force sensor 100C may further includes an overload protection layer 180. The overload protection layer 180 is filled in the cavity C. The overload protection layer 180 is filled in the cavity C after the step illustrated in FIG. 3H or FIG. 3J, for example. A top surface ST180 of the overload protection layer 180 is higher than a top surface ST124 of the force receiving portion 124, such that an external force applied to the MEMS force sensor 100C is first acted on the overload protection layer 180. A rigidity of the overload protection layer 180 is less than a rigidity of the second substrate 120, and thereby, part of the external force may be absorbed by the overload protection layer 180, so as to achieve a stress buffering effect. For example, a material of the overload protection layer 180 may include a polymer, but the invention is not limited thereto.

In addition, in an MEMS force sensor 100D illustrated in FIGS. 6A and 6B, an overload protection layer 180A may also be disposed on the surface S of the deformable portion 122 facing the first substrate 110 and expose the conductive terminals 130. In particular, the circuit structure CS may be located between the deformable portion 122 and the overload protection layer 180A, and a gap G is kept between the overload protection layer 180A and the first substrate 110. A method for fabricating the overload protection layer 180A may include entirely covering an overload protection material layer on the second inter-layer dielectric layer 160 and the pads 170 after the step illustrated in FIG. 3H, and then removing a portion of the overload protection material layer by a patterning process (e.g., a dry etching process) to expose a region to contain the conductive terminals 130, but the invention is not limited thereto.

Since the overload protection layer 180A is disposed on the deformable portion 122, the rigidity of the overload protection layer 180A may influence a deformation degree of the deformable portion 122. Namely, the rigidity of the overload protection layer 180A may influence sensing sensitivity. In the present embodiment, the sensing sensitivity may be fine-tuned through changing a material of the overload protection layer 180A. For example, the material of the overload protection layer 180A may include a polymer, but the invention is not limited thereto.

Additionally, a size of the gap G determines a maximum pressing-down distance of the MEMS force sensor 100C. Therefore, in the present embodiment, the size of the gap G may be modulated (for example, by keeping the gap G smaller than a maximum deformation of the deformable portion 122) to prevent the deformable portion 122 from being damaged due to the pressing-down distance being greater than the maximum deformation of the deformable portion 122.

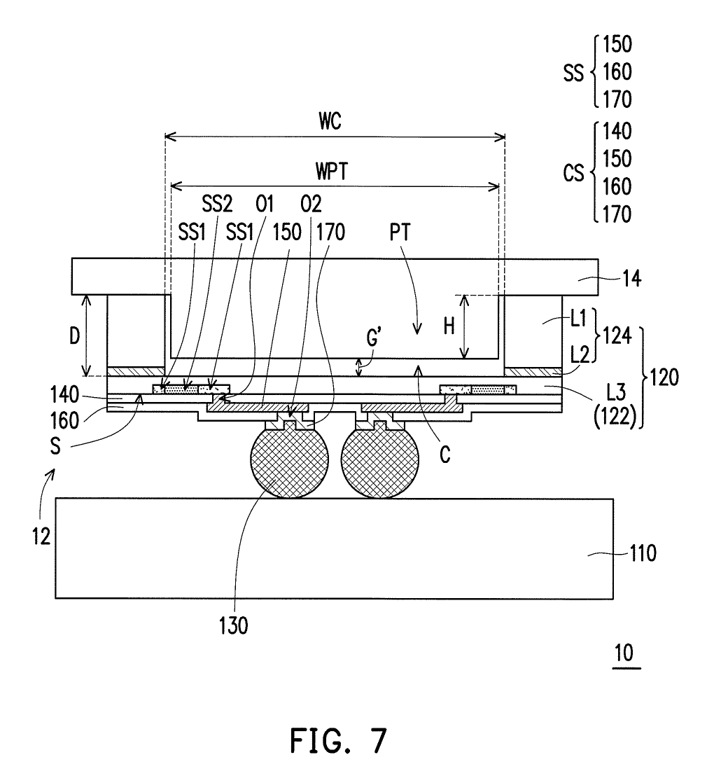

FIG. 7 is a schematic cross-sectional view of a force sensing apparatus according to an embodiment of the invention. With reference to FIG. 7, a force sensing apparatus 10 includes an MEMS force sensor 12 and a third substrate 14. In the present embodiment, the MEMS force sensor 12 uses the structure of the MEMS force sensor 100A illustrated in FIG. 3J, but the invention is not limited thereto. In other embodiments, the MEMS force sensor 12 may also use the structure illustrated in FIG. 4, FIG. 5 or FIG. 6A. Descriptions related to the same or like elements may refer to the embodiments above and will not be repeated hereinafter.

The third substrate 14 has a protruding portion PT. A width WPT of the protruding portion PT is less than a width WC of the cavity C, and a thickness H of the protruding portion PT is less than a depth D of the cavity C. Thereby, when the third substrate 14 is assembled onto the second substrate 120, the protruding portion PT may be embedded in the cavity C, which facilitates improving the convenience of alignment.

Additionally, in the present embodiment, the size of a gap G′ between the protruding portion PT and the deformable portion 122 may be modulated to modulate a pressure range of the the deformable portion 122. For example, the gap G′ may be less than the maximum deformation of the deformable portion 122 to prevent the deformable portion 122 from being damaged due to the pressing-down distance being greater than the maximum deformation of the deformable portion 122. In other words, the protruding portion PT facilitates not only improving the convenience of alignment, but also achieving an overload protection effect.

Based on different demands, other film layers may be disposed on the third substrate 14. For example, a touch element may be disposed on the third substrate 14, i.e., the third substrate 14 may be a substrate of a touch panel. In this way, the force sensing apparatus 10 may further provide a two-dimensional sensing function in addition to the force sensing function. Namely, the force sensing apparatus 10 is capable of not only detecting a force change in a Z-axial direction, but also detecting a touched coordinate on the X-Y plane. However, the invention is not limited thereto. In another embodiment, the third substrate 14 may also be a substrate of a display panel.

To summarize, in the exemplary embodiments of the invention, the deformable portion has a plurality of sensing elements, and the force receiving portion protrudes from the surface of the deformable portion which is back facing to the first substrate. When an external force is applied to the force receiving portion, the deformable portion receives a pressing-down force and is deformed, and the sensing elements in the deformable portion correspondingly generate a physical quantity change, such that the MEMS force sensor and the force sensing apparatus having the MEMS force sensor can determine the change of the force applied to the MEMS force sensor or the force sensing apparatus according to the physical quantity change. In other embodiments, the MEMS force sensor can further be equipped with the overload protection layer to provide the stress buffering or overload protection effect. Moreover, the third substrate of the force sensing apparatus which is designed with the protruding portion can facilitate not only improving the convenience of alignment but also achieving the overload protection effect.

Although the invention has been disclosed by the above embodiments, they are not intended to limit the invention. It will be apparent to one of ordinary skill in the art that modifications and variations to the invention may be made without departing from the spirit and scope of the invention. Therefore, the scope of the invention will be defined by the appended claims.

What is claimed is:

1. A micro-electro-mechanical system (MEMS) force sensor, comprising:
a first substrate;
a second substrate, disposed opposite to the first substrate and comprising:
a deformable portion, having a plurality of sensing elements; and
a force receiving portion, protruding from a surface of the deformable portion which is back facing to the first substrate, such that a cavity is formed above the deformable portion; and
a plurality of conductive terminals, electrically connected to the sensing elements and centrally disposed under the cavity, wherein the second substrate is fixed with the first substrate through the conductive terminals.

2. The MEMS force sensor according to claim 1, wherein the first substrate is a printed circuit board (PCB) or a display panel.

3. The MEMS force sensor according to claim 1, wherein the sensing elements comprises a plurality of connection portions and a plurality of piezoresistive sensing elements, each of the piezoresistive sensing elements is connected with two adjacent connection portions, each of four sides of the deformable portion has a sensing unit, and the sensing unit is composed of at least one of the piezoresistive sensing elements and multiple of the connection portions.

4. The MEMS force sensor according to claim 3, wherein orthographic projections of the piezoresistive sensing elements on the surface of the deformable portion which is back facing to the first substrate fall within a range covered by the cavity.

5. The MEMS force sensor according to claim 3, wherein the sensing elements are disposed near a central region of the deformable portion, and orthographic projections of the connection portions and the piezoresistive sensing elements on the surface of the deformable portion which is back facing to the first substrate fall within a range covered by the cavity.

6. The MEMS force sensor according to claim 1, wherein the second substrate further comprises:
a circuit structure, disposed on a surface of the deformable portion facing the first substrate, and the sensing elements are electrically connected to the conductive terminals through the circuit structure, wherein two adjacent sensing units share one of the conductive terminals through the circuit structure and form a Wheatstone bridge.

7. The MEMS force sensor according to claim 1, further comprising:
an overload protection layer, filled in the cavity, and a top surface of the overload protection layer being higher than a top surface of the force receiving portion.

8. The MEMS force sensor according to claim 7, wherein a rigidity of the overload protection layer is less than a rigidity of the second substrate.

9. The MEMS force sensor according to claim 1, further comprising:
an overload protection layer, disposed on a surface of the deformable portion facing the first substrate and exposing the conductive terminals, and a gap is kept between the overload protection layer and the first substrate.

10. A force sensing apparatus, comprising:
an MEMS force sensor, comprising:
a first substrate;
a second substrate, disposed opposite to the first substrate and comprising:
a deformable portion, having a plurality of sensing elements; and
a force receiving portion, protruding from a surface of the deformable portion which is back facing to the first substrate, such that a cavity is formed above the deformable portion; and
a plurality of conductive terminals, electrically connected to the sensing elements and centrally disposed under the cavity, wherein the second substrate is fixed with the first substrate through the conductive terminals; and
a third substrate, having a protruding portion, a width of the protruding portion being less than a width of the cavity, and a thickness of the protruding portion being less than a depth of the cavity, wherein the third substrate is assembled onto the second substrate, and the protruding portion is embedded in the cavity.

11. The force sensing apparatus according to claim 10, wherein the third substrate is a substrate of a touch panel or a substrate of a display panel.
